(19) United States
(12) Patent Application Publication
(10) Pub. No.: US 2008/0157277 A1
(43) Pub. Date: Jul. 3, 2008

(54) MIM CAPACITOR

(76) Inventors: Jeong-Ho Park, Seoul (KR); Ho-Yeong Choe, Seoul (KR)

Correspondence Address: SHERR & NOURSE, PLLC, 620 HERNDON PARKWAY, SUITE 200, HERNDON, VA, 20170, US

(21) Appl. No.: 11/964,562

(22) Filed: Dec. 26, 2007

(30) Foreign Application Priority Data
Dec. 28, 2006 (KR) 10-2006-0135795

(51) Int. Cl. H01L 21/283; H01L 29/92

(52) U.S. Cl. 257/532; 438/393; 257/E21.159; 257/E29.343

(57) ABSTRACT

Embodiments relate to a metal-insulator-metal (MIM) capacitor that may include a lower insulation layer where a capacitor lower metal layer is already formed, an intermediate structure, a first conductive structure, and a second conductive structure. The intermediate structure may include a first capacitor insulation pattern, a capacitor middle metal layer, a second capacitor insulation pattern, a capacitor upper metal layer, and an insulation pattern formed in sequence over the lower insulation layer. The first conductive structure may include a copper-based material and may be coupled between the capacitor upper metal layer and the capacitor lower metal layer. The second conductive structure may include a copper-based material and is coupled to the capacitor middle metal layer.

The present application claims priority under 35 U.S.C. 119 and 35 U.S.C. 365 to Korean Patent Application No. 10-2006-0135795 (filed on Dec. 28, 2006), which is hereby incorporated by reference in its entirety.

### BACKGROUND

As semiconductor integrated circuits are being implemented in various fields, analog capacitors formed in a logic circuit region may increasingly be required to have large capacitance and operate at high speed. The large capacitance of a capacitor may be obtained by decreasing the resistance of electrodes of the capacitor, which may reduce the dependency on frequency. The large capacitance of a capacitor may also be achieved by decreasing the thickness of a capacitor dielectric layer, using a high-K dielectric material, or increasing the area of the capacitor.

However, in a related art method of fabricating a capacitor, a ratio of a capacitor value (i.e., capacitance) to an effective area may be often small. Thus, the capacitor area may be increased to increase the capacitance. However, such an increase in the capacitor area may cause the chip area to be increased. As a result, the degree of integration may likely be decreased. When using a high-K dielectric material, additional apparatuses and new processes may need to be set up. Thus, the related art apparatuses may not be efficient or practicable.

### SUMMARY

Embodiments relate to a metal-insulator-metal (MIM) capacitor and a method for fabricating the same.

Embodiments relate to a metal-insulator-metal (MIM) capacitor and a method for fabricating the same, wherein the MIM capacitor may have an increased level of capacitance without increasing the chip area while using the related art apparatuses.

According to embodiments, a method for fabricating a metal-insulator-metal (MIM) capacitor may include forming a first capacitor insulation layer, a capacitor middle metal layer, a second capacitor insulation layer, a capacitor upper metal layer, an insulation layer, and a first photoresist pattern in sequence over a lower insulation layer where a capacitor lower metal layer is already formed, etching the insulation layer and the capacitor upper metal layer using the first photoresist pattern as a mask and may form an insulation pattern and a patterned capacitor upper metal layer, forming a second photoresist pattern over the insulation pattern and the second capacitor insulation layer, etching the second capacitor insulation layer and the capacitor middle metal layer using the second photoresist pattern as a mask and may form a second capacitor insulation pattern and a patterned capacitor middle metal layer, forming an dielectric layer and a photoresist pattern over the resultant structure provided after the etching, etching the dielectric layer using the third photoresist pattern as a mask and may form a first inter-layer insulation pattern including contact holes, filling the contact holes with a sacrificial photoresist material, forming a fourth photoresist pattern over the resultant structure provided after the filling, etching the first inter-layer insulation pattern and the sacrificial photoresist material using the fourth photoresist pattern as a mask and may form a second inter-layer insulation pattern including trenches, removing the sacrificial photoresist material filled in the contact holes, performing a blanket etch-back process to expose the patterned capacitor upper metal layer, the capacitor lower metal layer, and the patterned capacitor middle metal layer, and forming a conductive structure over the second inter-layer insulation pattern, the conductive structure including a copper-based material.

According to embodiments, a MIM capacitor may include a lower insulation layer where a capacitor lower metal layer is already formed, an intermediate structure including a first capacitor insulation pattern, a capacitor middle metal layer, a second capacitor insulation pattern, a capacitor upper metal layer, and an insulation pattern formed in sequence over the lower insulation layer, a first conductive structure including a copper-based material and coupled between the capacitor upper metal layer and the capacitor lower metal layer, and a second conductive structure including a copper-based material and coupled to the capacitor middle metal layer.

According to embodiments, in the MIM capacitor, a first portion “A” of the conductive structure 19 (see FIG. 7) coupled to the patterned capacitor upper metal layer 11′ and to the capacitor lower metal layer 4 may function as a top plate of the capacitor. A second portion “B” of the conductive structure 19 (see FIG. 7) coupled to the patterned capacitor middle metal layer 7′ may function as a bottom plate of the capacitor. The capacitor including the patterned capacitor middle metal layer and the patterned capacitor upper metal layer and the capacitor including the patterned capacitor middle metal layer and the capacitor lower metal layer may be coupled together in parallel, so that the overall capacitance may be increased.

According to embodiments, the capacitance of the capacitor may be increased without increasing the chip area while still using the related art apparatuses. As a result, the chip size may be minimized and the integration scale of semiconductor devices may be improved.

### DRAWINGS

FIGS. 1 through 7 are sectional drawings illustrating a metal-insulator-metal (MIM) capacitor and a method for fabricating a metal-insulator-metal (MIM) capacitor in accordance with embodiments.

### DESCRIPTION

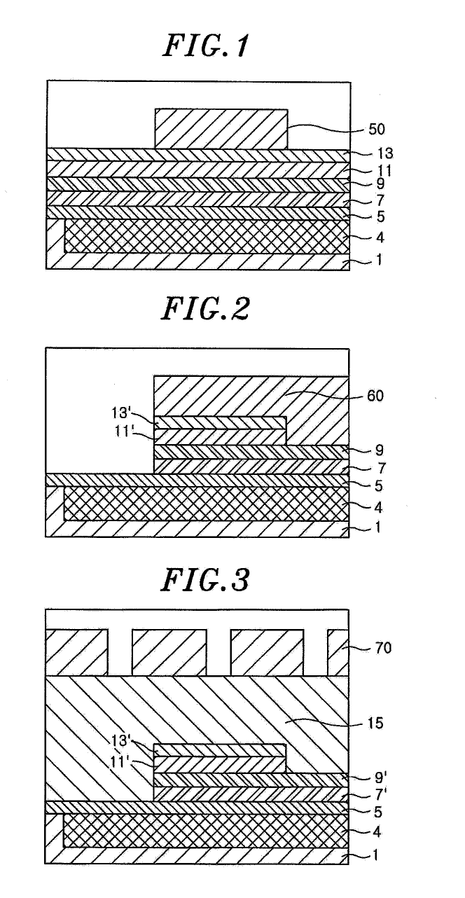

Referring to FIG. 1, first capacitor insulation layer 5, capacitor middle metal layer 7, second capacitor insulation layer 9, capacitor upper metal layer 11, and insulation layer 13 may be formed over lower insulation layer 1 where capacitor lower metal layer 4 is already formed. Insulation layer 13 may include a nitride-based material, and insulation layer 13 and first and second capacitor insulation layers 5 and 9 may include substantially the same material. Each of first and second capacitor insulation layers 5 and 9 may be formed to a thickness ranging from about 450 Å to 700 Å. First capacitor insulation layer 5 and second capacitor insulation layer 9 may have substantially the same thickness. Insulation layer 13 including a nitride-based material may have a thickness greater than first and second capacitor insulation layers 5 and 9.

Capacitor lower metal layer 4 may include a copper-based material, and capacitor upper metal layer 11 and capacitor middle metal layer 7 may include one selected from a group consisting of titanium (Ti), titanium (Ti)/titanium nitride (TiN), and Ti/aluminum (Al)/TiN.

A photoresist film may be coated over insulation layer 13, and exposed to light and developed and may form first photoresist pattern 50.

Referring to FIG. 2, insulation layer 13 and capacitor upper metal layer 11 may be etched using first photoresist pattern 50 as a mask and may form insulation pattern 13′ and patterned capacitor upper metal layer 11′. The etching may be a dry etch or a chemical dry etch (CDE). First photoresist pattern 50 may be removed by an ashing method.

A photoresist film may be coated over the above resultant surface profile, and exposed to light and developed and may form second photoresist pattern 60. Second photoresist pattern 60 may be formed to cover insulation pattern 13′ and patterned capacitor upper metal layer 11′ and expose the surface of second capacitor insulation layer 9. Second photoresist pattern 60 may be formed to be aligned with one edge of insulation pattern 13′ and patterned upper metal layer 11′ and cover another edge of insulation pattern 13′ and patterned capacitor upper metal layer 11′.

Referring to FIG. 3, second capacitor insulation layer 9 and capacitor middle metal layer 7 may be etched using second photoresist pattern 60 as a mask and may form second capacitor insulation pattern 9′ and patterned capacitor middle metal layer 7′. The etching may be performed using a dry etch or a CDE. Dielectric layer 15 may be formed over the above resultant surface profile. A photoresist film may be coated over dielectric layer 15, and subjected to photolithography and may form third photoresist pattern 70.

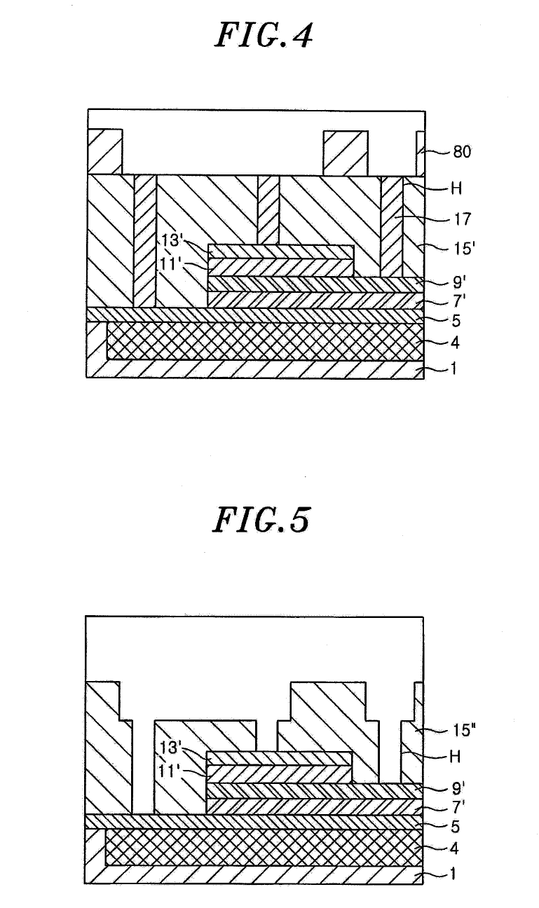

Referring to FIG. 4, dielectric layer 15 may be etched using third photoresist pattern 70 and may form first inter-layer insulation pattern 15′ where contact holes H may be formed therein. Third photoresist pattern 70 may be removed. Sacrificial photoresist material 17 may fill contact holes H. A photoresist film may be coated over the above resultant structure provided after the filling of sacrificial material 17, and exposed to light and developed and may form fourth photoresist pattern 80.

Referring to FIG. 5, a portion of first inter-layer insulation pattern 15′ and sacrificial photoresist material 17 may be etched using fourth photoresist pattern 80 as a mask and may form second inter-layer insulation pattern 15″ where trenches may be formed therein. Fourth photoresist pattern 80 may be removed by an ashing method. According to embodiments, sacrificial photoresist material 17 filling contact holes H may be removed.

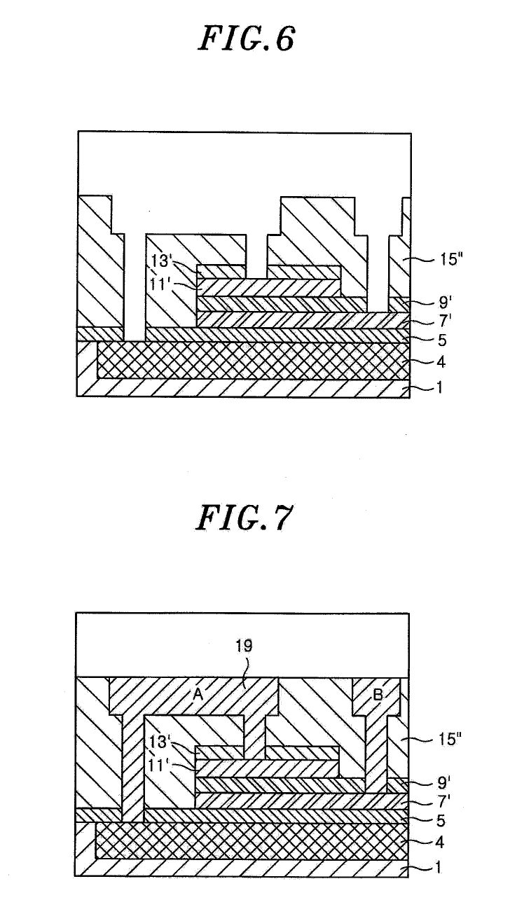

Referring to FIG. 6, a blanket etch-back process may be performed on the resultant structure illustrated in FIG. 5. According to embodiments, insulation pattern 13′, first capacitor insulation layer 5, and second capacitor insulation pattern 9′ may be etched to expose patterned capacitor upper metal layer 11′, capacitor lower metal layer 4, and patterned capacitor middle metal layer 7′. Second inter-layer insulation pattern 15″ may also be etched to a certain thickness which may be substantially the same as the thickness of insulation pattern 13′, first capacitor insulation layer 5 and second capacitor insulation pattern 9′.

Referring to FIG. 7, an electrolytic plating process may be performed on second inter-layer insulation pattern 15″ and may form a copper layer over the resultant structure obtained after the blanket etch-back process. The copper layer may be electrically and mechanically polished and may form a copper-based conductive structure 19.

According to embodiments, a MIM capacitor may include a first portion A of conductive structure 19 (see FIG. 7) coupled to patterned capacitor upper metal layer 11′ and to capacitor lower metal layer 4 may function as a top plate of the capacitor. A second portion B of conductive structure 19 (see FIG. 7) coupled to patterned capacitor middle metal layer 7′ may function as a bottom plate of the capacitor. The capacitor including the patterned capacitor middle metal layer and the patterned capacitor upper metal layer and the capacitor including the patterned capacitor middle metal layer and the capacitor lower metal layer may be coupled together in parallel, and the overall capacitance may be increased.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method, comprising:
forming a capacitor lower metal layer over a lower insulation layer;
forming a first capacitor insulation pattern, a capacitor middle metal layer, a second capacitor insulation pattern, a capacitor upper metal layer, and an insulation pattern over the lower insulation layer;
forming a dielectric layer over the lower insulation layer;
etching the dielectric layer to form a first inter-layer insulation pattern including contact holes;
filling the contact holes with a sacrificial photoresist material;
etching the first inter-layer insulation pattern and the sacrificial photoresist material to form a second inter-layer insulation pattern including trenches;
removing the sacrificial photoresist material filled in the contact holes;
performing a blanket etch-back process to expose the patterned capacitor upper metal layer, the capacitor lower metal layer, and the patterned capacitor middle metal layer; and
forming a conductive structure over the second inter-layer insulation pattern.

2. The method of claim 1, wherein the etching is performed using a photoresist pattern as a mask.

3. The method of claim 1, wherein the conductive structure comprises a copper-based material.

4. The method of claim 1, wherein the first and second capacitor insulation patterns have a substantially identical thickness, and the insulation pattern has a thickness greater than that of the first and second capacitor insulation patterns.

5. The method of claim 1, wherein the capacitor lower metal layer comprises a copper-based material.

6. The method of claim 1, wherein the capacitor upper metal layer and the capacitor middle meta layer each comprise a least one of titanium (Ti), Ti/titanium nitride (TiN), and Ti/aluminum (Al)/TiN.

7. The method of claim 1, wherein the second photoresist pattern is formed to cover the insulation pattern and the patterned capacitor upper metal layer and expose the second capacitor insulation layer.

8. The method of claim 1, wherein the second photoresist pattern is formed to be aligned with one edge of the insulation pattern and the patterned capacitor upper metal layer and to cover another edge of the insulation pattern and the patterned capacitor upper metal layer.

9. A device, comprising:
a capacitor lower metal over a lower insulation layer;
an intermediate structure including a first capacitor insulation pattern, a capacitor middle metal layer, a second capacitor insulation pattern, a capacitor upper metal layer, and an insulation pattern over the lower insulation layer;
a first conductive structure including a copper-based material coupled between the capacitor upper metal layer and the capacitor lower metal layer; and
a second conductive structure including a copper-based material and coupled to the capacitor middle metal layer.

10. The device of claim 9, wherein the capacitor lower metal layer comprises a copper-based material.

11. The device of claim 9, wherein the capacitor upper metal layer and the capacitor middle metal layer each include at least one of titanium (Ti), Ti/titanium nitride (TiN), and Ti/aluminum (Al)/TiN.

12. The device of claim 9, wherein the insulation pattern comprises an insulation material substantially the same as a material used for forming the first and second capacitor insulation patterns.

13. The device of claim 9, wherein the first capacitor insulation pattern, the capacitor middle metal layer, the second capacitor insulation pattern, the capacitor upper metal layer, and the insulation pattern are formed in sequence over the lower insulation layer.

14. A device, comprising:
a capacitor lower metal layer over a lower insulation layer;
a capacitor upper metal layer over the capacitor lower metal layer and the lower insulation layer;
a capacitor middle metal layer coupled between the lower insulation layer and the capacitor upper metal layer;
a first conductive structure coupled between the capacitor upper metal layer and the capacitor lower metal layer; and
a second conductive structure coupled to the capacitor middle metal layer.

15. The device of claim 14, wherein the first and second conductive structures each comprise a copper-based material.

16. The device of claim 15, wherein the capacitor lower metal layer comprises a copper-based material.

17. The device of claim 15, wherein the capacitor upper metal layer and the capacitor middle metal layer each include at least one of titanium (Ti), Ti/titanium nitride (TiN), and Ti/aluminum (Al)/TiN.

18. The device of claim 15, further comprising a middle insulation layer over the capacitor middle metal layer and an upper insulation layer over the capacitor upper metal layer, wherein the lower insulation layer, middle insulation layer, and upper insulation layer comprise a substantially same material.

19. The device of claim 15, wherein the lower and middle insulation layers have substantially the same thickness, and the upper insulation layer has a thickness greater than that of the lower and middle insulation layers.
